(19) United States
(12) Patent Application Publication
(10) Pub. No.: US 2010/0097696 A1
(43) Pub. Date: Apr. 22, 2010

(54) Sheet glass for microscopy and manufacturing method thereof

(76) Inventor: Kuang-Yuan Lin, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/314,941

(22) Filed: Dec. 19, 2008

(30) Foreign Application Priority Data
Oct. 17, 2008 (TW) 97139831

(51) Int. Cl. G02B 21/34; C03C 17/09; C03C 17/06; C23C 14/34; C23C 14/24; C25D 7/00; C25D 5/02

(52) U.S. Cl. 359/392; 359/397; 427/164; 427/166; 204/192.1; 427/250; 205/112

(57) ABSTRACT

A sheet glass for microscopy includes a base plate and a metal pattern configured on the base plate. The structure of the sheet glass increases the throughput, reduces the cost and shortens the distance between grids and targets for keeping grids and targets within the depth of field of the microscope. A manufacturing method of sheet glass for microscopy is also disclosed.

### BACKGROUND OF THE INVENTION

1. Field of the Invention

The present invention relates to a sheet glass for microscopy, and more particularly to a sheet glass for microscopy including a metal pattern.

2. Description of the Prior Art

FIG. 1 is a sectional view illustrating a conventional sheet glass set for biological specimen counting. The conventional sheet glass set for biological specimen counting is formed by high-precision grinding, wherein a groove 61 in a microscope slide 6 has a depth precision of 10 μm. A cover slip 7 is placed over the groove 61 slide so that it presses down due to its own weight to drain the redundant biological specimen out of the groove 61, and the swelling effect is thus prevented. The detection space formed by the microscope slide 6 and cover slip 7 has a height of 5 μm to 10 μm so that targets (e.g. sperms, blood cells, and oocytes) in the biological specimen are mobile despite being compressed and can be precisely counted. The aforementioned sheet glass set for biological specimen counting is therefore highly expensive due to the requirement of high-precision grinding process.

In addition, in a case of too large a detection space formed by the microscope slide 6 and the cover slip 7 for targets, the targets which are suspended in the biological specimen may be too distant from the grids configured on the cover slip 7 to keep the grids and the targets within the depth of view-field or focus of the microscope simultaneously; therefore, the grids and targets may not be clearly viewed at the same time.

Hence, it is now a current goal to reduce the cost for manufacturing of sheet glass set for biological specimen counting and to shorten the distance between target and grids of sheet glass set for biological specimen counting.

### SUMMARY OF THE INVENTION

The present invention is directed to provide a sheet glass for microscopy and manufacturing method thereof that allow higher throughput, reduce cost and shortens the distance between grids and targets for keeping grids and targets within the depth of view-field or focus of the microscope.

A sheet glass for microscopy according to an embodiment of the present invention includes a base plate and a metal pattern configured on the base plate.

A manufacturing method of sheet glass for microscopy according to another embodiment of the present invention includes providing a base plate; and configuring a metal pattern on the base plate, wherein the metal pattern is formed by a vacuum evaporation, a sputtering or an electroplating process, or any combination thereof.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a sectional view illustrating a conventional sheet glass set for biological specimen counting;

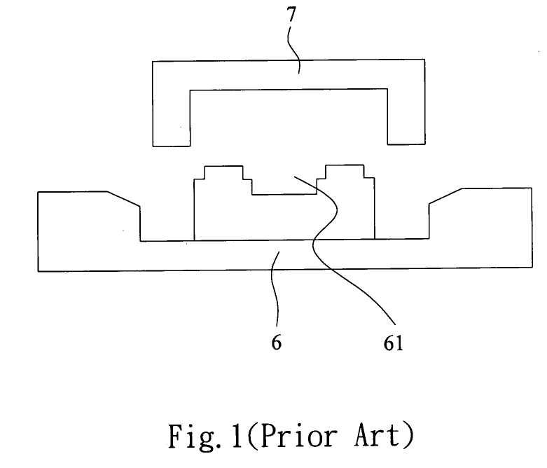

FIG. 2 is a side-view illustrating a sheet glass set for microscopy according to an embodiment of the present invention;

FIG. 3 is a top-view diagram illustrating a first sheet glass according to another embodiment of the present invention; and

FIG. 4 is a top-view illustrating a second sheet glass according to yet another embodiment of the present invention.

### DESCRIPTION OF THE PREFERRED EMBODIMENT

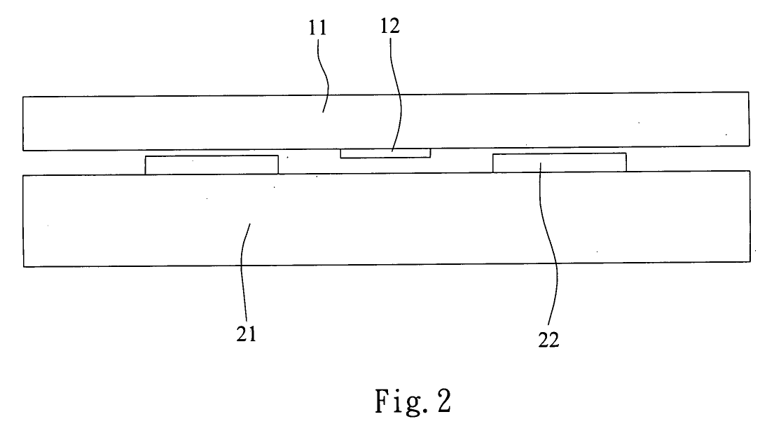

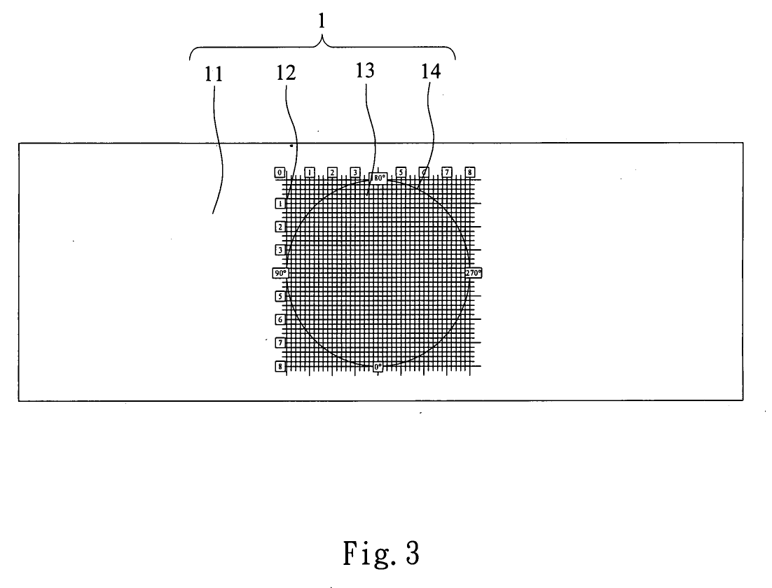

FIG. 2 is a side-view illustrating a sheet glass set for microscopy according to an embodiment of the present invention, and FIG. 3 is a top-view illustrating a first sheet glass according to another embodiment of the present invention. The first sheet glass 1 according to an embodiment of the present invention includes a first base 11 and a plurality of metal grids 12 configured on the base plate 11, wherein the metal grids 12 defines a plurality of specimen counting areas 13.

It should be noted that the metal grids 12 may be formed by a vacuum evaporation, a sputtering or an electroplating process, or any combination thereof. More specifically, vacuum evaporation process may be performed to evaporate the metal molecules under a vacuum environment to form a thin film of the metal molecules on the first base plate 11. Sputtering process may be performed for bombarding target material with argon ion, converting the target material molecule into gas phase, and coating target material molecule onto the first base plate 11. Electroplating process may be performed by dissociating the metal ion from the cathode and coating the metal ion onto the first base plate 11.

As described above, the metal grids 12 may be formed by a vacuum evaporation, a sputtering or an electroplating process, or any combination thereof. That is, the metal grids 12 may be formed by first forming a thin film on the first base plate 11 via vacuum evaporation or sputtering and then thickening the thin film to a pre-determined thickness via an electroplating process, for example.

As illustrated in FIG. 3, in the present embodiment, the specimen counting areas 13 defined by metal grids 12 comprise a square-shape, i.e. the horizontal and vertical metal grids intersect and arranged perpendicular to each other to form a plurality of square-shaped grids 12.

In an embodiment, the metal grids 12 comprise a pre-determined height in a range between of 0.3 nm and 100 μm. The above-mentioned pre-determined height is controlled precisely to constrain mobile space of target (e.g. sperms, blood cells, and oocytes).

The first sheet glass 1 of the present invention may further include a positioning circle 14 formed by a vacuum evaporation, a sputtering or an electroplating process, or any combination thereof, and may be used for positioning the target.

In one embodiment, the first base plate 11 is transparent for use in an optical microscopy and may be made of glass or acrylic resin.

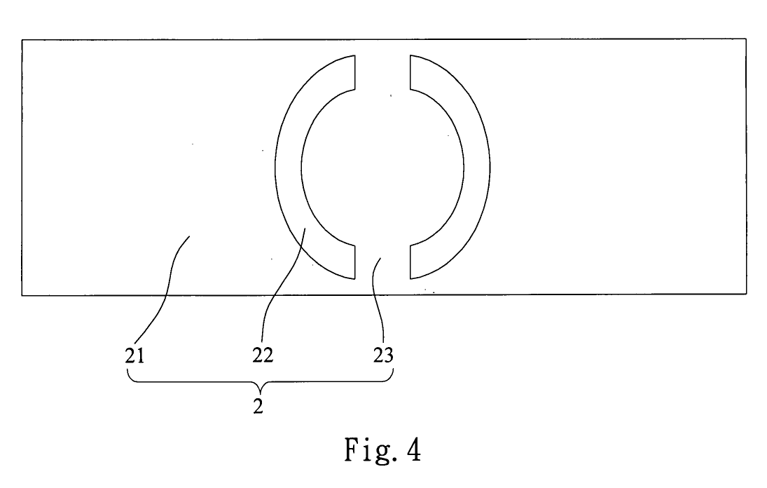

FIG. 4 is a top-view illustrating a second sheet glass 2 according to an embodiment of the present invention. As illustrated in FIG. 4, the second sheet glass 2 includes a second base plate 21 and a metal wall 22 configured on the second base plate 21, and the metal wall 22 defines a concave space. The second sheet glass 2 is thus formed.

The metal wall 22 may be formed by a vacuum evaporation, a sputtering or an electroplating process, or any combination thereof. The concave space is used for mounting biological specimen for subsequent analysis. The metal wall 22 comprises at least one opening 23 for draining redundant biological specimen that is dropped into the concave space. Here, the metal wall 22 may be formed by using the process to form the above-mentioned metal grids 12, and the material of the second base plate 21 may be the same as that of the first base plate 11, and the detailed description thereof is therefore not repeated.

In one example, the above-mentioned metal wall 22 comprises a pre-determined height in a range between 0.3 nm and 100 μm. The above-mentioned pre-determined height may be precisely controlled to constrain mobile space of target.

To sum up, the sheet glass of the present invention includes a base plate and a metal pattern configured on the base plate, wherein the metal pattern includes aforementioned metal grids, positioning circle, or metal wall.

The following describes the application of the -present invention according one embodiment. Referring to FIG. 2 and FIG. 4, the concave space defined by the metal wall 22 of the second sheet glass 2 is used for mounting biological specimen containing target. The first sheet glass 1 is laid against the second sheet glass 2 with the face of metal grids 12 to drain the redundant biological specimen via the opening 23. The sheet glass set formed with the first sheet glass 1 and second sheet glass 2 may be used for subsequent observation and target counting in an optical microscope.

Here, the metal grids 12 and the metal wall 22 are formed via a vacuum evaporation, a sputtering or an electroplating process, or any combination thereof. Therefore, the present invention may have the advantage to precisely control the height of the metal grids 12 and the metal wall 22 due to high-precision feature of the manufacturing method. Also, vacuum evaporation, sputtering, and electroplating processes have the advantage of higher throughput and low cost compared to the conventional process. Furthermore, the sheet glass of the present invention may shorten the distance between the target and the metal grids 12 by the protruding metal grids 12 with pre-determined height into the concave space defined by the metal wall 22 and effectively increase the capability of simultaneously confining the targets and the metal grids within the depth of view-field or focus of the microscope.

To sum up, the present -invention achieves higher throughput, reduces the cost and shortens the distance between grids and targets for keeping grids and targets within the depth of field of the microscope.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A sheet glass for microscopy, comprising:
a base plate; and
a metal pattern configured on the base plate.

2. The sheet glass for microscopy as claimed in claim 1, wherein the metal pattern comprises a plurality of metal grids defining a plurality of specimen counting areas.

3. The sheet glass for microscopy as claimed in claim 2, wherein the specimen counting areas comprise a square-shape.

4. The sheet glass for microscopy as claimed in claim 2, wherein the metal pattern comprises a positioning circle.

5. The sheet glass for microscopy as claimed in claim 1, wherein the metal pattern comprises a metal wall having at least one opening.

6. The sheet glass for microscopy as claimed in claim 1, wherein the metal pattern comprises a pre-determined height in a range between 0.3 nm and 100 μm.

7. The sheet glass for microscopy as claimed in claim 1, wherein the base plate is comprised of glass or acrylic resin.

8. The sheet glass for microscopy as claimed in claim 1, wherein the base plate is transparent.

9. A manufacturing method of sheet glass for microscopy, comprising:
providing a base plate; and
configuring a metal pattern on the base plate, wherein the metal pattern is formed by a vacuum evaporation, a sputtering or an electroplating process, or any combination thereof.

10. The manufacturing method as claimed in claim 9, wherein the metal pattern comprises a plurality of metal grids defining a plurality of specimen counting areas.

11. The manufacturing method as claimed in claim 10, wherein the specimen counting areas comprise a square-shape.

12. The manufacturing method as claimed in claim 10, wherein the metal pattern comprises a positioning circle.

13. The manufacturing method as claimed in claim 9, wherein the metal pattern comprises a metal wall having, at least one opening.

14. The manufacturing method as claimed in claim 9, wherein the metal pattern has a pre-determined height in a range between 0.3 nm and 100 μm.

15. The manufacturing method as claimed in claim 9, wherein the base plate is comprised of glass or acrylic resin.

16. The manufacturing method as claimed in claim 9, wherein the base plate is transparent.
